(19) United States
(12) Patent Application Publication
(10) Pub. No.: US 2025/0060936 A1
(43) Pub. Date: Feb. 20, 2025

(54) METHOD AND APPARATUS FOR USE IN THE DESIGN AND MANUFACTURE OF INTEGRATED CIRCUITS

(71) Applicant: Imagination Technologies Limited, Kings Langley (GB)

(72) Inventors: Theo Alan Drane, London (GB); Wai-Chuen Cheung, London (GB)

(21) Appl. No.: 18/937,707

(22) Filed: Nov. 5, 2024

Related U.S. Application Data
(63) Continuation of application No. 18/241,977, filed on Sep. 4, 2023, now Pat. No. 12,169,700.
Application No. 18/241,977 is a continuation of application No. 16/694,915, filed on Nov. 25, 2019, now Pat. No. 11,748,060.
Application No. 16/694,915 is a continuation of application No. 16/229,499, filed on Dec. 21, 2018, now Pat. No. 10,540,141.
Application No. 16/229,499 is a continuation of application No. 15/898,455, filed on Feb. 17, 2018, now Pat. No. 10,162,600.
Application No. 15/898,455 is a continuation of application No. 13/626,886, filed on Sep. 26, 2012, now Pat. No. 9,933,997.

(30) Foreign Application Priority Data
Oct. 6, 2011 (GB) 1117318.4

(51) Int. Cl. G06F 7/38; G06F 7/535; G06F 30/00; G06F 30/30; G06F 30/327

(52) U.S. Cl. CPC G06F 7/38; G06F 7/535; G06F 30/00; G06F 30/30; G06F 30/327

(57) ABSTRACT

A method and apparatus are provided for manufacturing integrated circuits performing invariant integer division x/d. A desired rounding mode is provided and an integer triple (a,b,k) for this rounding mode is derived. Furthermore, a set of conditions for the rounding mode is derived. An RTL representation is then derived using the integer triple. From this a hardware layout can be derived and an integrated circuit manufactured with the derived hardware layout. When the integer triple is derived a minimum value of k for the desired rounding mode and set of conditions is also derived. 0

### CROSS-REFERENCE TO RELATED APPLICATIONS

This application claims priority from GB App. No. 1117318.4, filed on Oct. 6, 2011, and which is incorporated by reference in its entirety herein.

### BACKGROUND

### Field

The following relates to methods and apparatus for use in the design and manufacture of integrated circuits, and particularly to the design and manufacture of circuits that perform divisions.

### Related Art

When designing and manufacturing ICs, sophisticated synthesis tools such as Synopsis

TM Design Compiler are used to convert a desired function which must be implemented in the IC into a set of logic gates to perform the functions. Functions which need to be implemented include add, subtract, multiply and divide. The synthesis tools seek to implement the desired functions in an efficient manner in logic gates.

The tools operate by converting a function to be implemented, such as divide by x, to what is known as register transfer level (RTL), which defines a circuit's behavior in terms of the flow of signals between hardware registers and the logical operations performed on these signals. This is then used to generate a high level representation of a circuit from which appropriate gate level representations and the ultimate IC design can be derived for manufacture, and an IC can then be made. If a synthesis tool is presented with division by a constant, it will invariably use

RTL designed for non-constant division. A designer could note that in the case of constant division an implementation of the form (ax+b)/2^{k} could potentially make smaller ICs. The designer would then have to work out values for the triple (a,b,k) which would perform the task of x/d.

Division is acknowledged to be an expensive operation to perform in hardware. However in the case where the divisor is known to be a constant, efficient hardware implementations can be constructed. Consider the division of an unsigned n bit integer x by a known invariant integer constant d:

$$\frac{x}{d} x ∈ [ 0 , {2}^{n} - 1 ] d ∈ N$$

For the purposes of the exposition we will assume that d is an odd integer larger than 1, the following schemes can be easily modified for even d by those skilled in the art. We consider an implementation of the form:

$$\frac{x}{d} \approx ⌊ \frac{ax + b}{{2}^{k}} ⌋$$

Where a, b and k are non negative integers. Note that without loss of generality we can assume that a is odd. The prior art in the case where the rounding used is round towards zero and d is an unsigned m bit number comes from [1] and can be succinctly summarised setting:

$$⌊ \frac{x}{d} ⌋ = ⌊ \frac{ax + b}{{2}^{k}} ⌋$$

$$t = ⌊ \frac{{2}^{n + m - 1}}{d} ⌋$$

$$k = n + m - 1$$

$$a = ( d ( t - 1 ) mod {2}^{n} \leq {2}^{m - 1} ) ? t + 1 : t$$

$$b = ( d ( t - 1 ) mod {2}^{n} \leq {2}^{m - 1} ) ? 0 : t$$

The second piece of prior art comes from [2] where the rounding mode used is round to nearest, d=2ⁿ−1 and x is the result of a multiplication of two unsigned n bit numbers a and b:

$$⌊ \frac{ab}{{2}^{n} - 1} + \frac{1}{2} ⌋ = ⌊ \frac{( {2}^{n} + 1 ) ( ab + {2}^{n - 1} )}{{2}^{2 n}} ⌋$$

When a division is to be performed such as divide by d, the integer triple discussed above is generated and provided to a RTL generation unit, which produces the gate level circuits required as an input to a synthesis tool which then generates the hardware components required for manufacture.

### SUMMARY

Aspects include methods and apparatus to design an integrated circuit for performing invariant integer division for a desired rounding mode such as round towards zero, round to nearest and faithful rounding, and integrated circuits according to such design.

In an example, the necessary and sufficient conditions for a given integer triple of (a,b,k) to give the required answer for a desired rounding mode are produced. In the application of a hardware scheme an algorithm is presented which will fit into a synthesis flow and produce the most efficient hardware. In particular, we have appreciated that by representing integer division in the form (ax+b)/2^{k} and implementing this, rather than the conventional x/d division input to an RTL generator, that the division is implemented using a multiply-add implementation for various rounding modes. Three rounding modes are described here but the principle can be extended to any rounding mode. Using such an approach results in a hardware implementation for the division which can have up to a 50% decrease in integrated circuit area required.

In accordance with one aspect, there is provided a method for manufacturing an integrated circuit for performing invariant integer division (x/d) comprises: deriving a integer triple (a,b,k) for a desired rounding mode and set of conditions where x/d=(ax+d)/2^{k}; deriving an RTL representation of the (ax+d)/2^{k} representation of the division using the integer triple; deriving a minimum value of k for a desired rounding mode and a set of conditions deriving a hardware layout from the RTL representation; and manufacturing an integrated circuit with the derived hardware layout.

### BRIEF DESCRIPTION OF THE DRAWINGS

FIG. 1 shows a block diagram of circuitry embodying an example according to the disclosure.

FIG. 2 shows a method that can be implemented in examples according to the disclosure.

FIG. 3 depicts apparatus that can be used to implement aspects of the disclosure.

### DETAILED DESCRIPTION

Exemplary aspects of the disclosure are described with reference to three rounding modes. Other rounding modes may also be implemented.

We first present the necessary and sufficient conditions for a given triple of (a,b,k) to implement each of the three following rounding schemes.

### Round Towards Zero (RTZ)

In this case we require:

$$⌊ \frac{x}{d} ⌋ = ⌊ \frac{ax + b}{{2}^{k}} ⌋$$

$$0 \leq \frac{ax + b}{{2}^{k}} - ( \frac{x - ( x mod d )}{d} ) < 1$$

$$x ( 1 - \frac{ad}{{2}^{k}} ) - \frac{bd}{{2}^{k}} \leq x mod d < x ( 1 - \frac{ad}{{2}^{k}} ) - \frac{bd}{{2}^{k}} + d$$

Now the sawtooth function x mod d is discontinuous in x with peaks at x=md−1 where 1≤m ≤floor (2ⁿ/d) and troughs at x=md for 0≤m≤floor (2ⁿ/d). It suffices to check that the upper bound error condition is met for md-1 and the lower bound error condition is met for md:

$$\begin{matrix}md ( 1 - \frac{ad}{{2}^{k}} ) - \frac{bd}{{2}^{k}} \leq 0 & d - 1 < ( md - 1 ) ( 1 - \frac{ad}{{2}^{k}} ) - \frac{bd}{{2}^{k}} + d \\ m ( {2}^{k} - ad ) \leq b & m ( ad - {2}^{k} ) < a - b \\ where 0 \leq m \leq ⌊ \frac{{2}^{n}}{d} ⌋ & where 0 < m \leq ⌊ \frac{{2}^{n}}{d} ⌋\end{matrix}$$

k Now given that a and d is odd then ad−2^{k}≠0. Depending on the sign of ad −2^{k} different values of m will stress these inequalities. It follows that the necessary and sufficient conditions for the implementation of round towards zero mode for the IC design is:

$$\begin{matrix}⌊ \frac{x}{d} ⌋ = ⌊ \frac{ax + b}{{2}^{k}} ⌋ \\ x ∈ [ 0 , {2}^{n} - 1 ]\end{matrix} ⇔ \begin{matrix}- \frac{b + 1}{⌊ {2}^{n} / d ⌋} < ad - {2}^{k} < a - b if ad - {2}^{k} < 0 \\ ad - {2}^{k} < \frac{a - b}{⌊ {2}^{n} / d ⌋} if ad - {2}^{k} > 0\end{matrix}$$

### Round to Nearest (RTN)

In this case we require:

$$⌊ \frac{x}{d} + \frac{1}{2} ⌋ = ⌊ \frac{ax + b}{{2}^{k}} ⌋$$

$$0 \leq \frac{ax + b}{{2}^{k}} - ( \frac{( 2 x + d ) - ( ( 2 x + d ) mod d}{2 d} ) < 1$$

$$2 x ( 1 - \frac{ad}{{2}^{k}} ) - \frac{bd}{{2}^{k - 1}} + d \leq ( 2 x + d ) mod 2 d < 2 x ( 1 - \frac{ad}{{2}^{k}} ) - \frac{bd}{{2}^{k - 1}} + 3 d$$

Now the sawtooth function (2x+d) mod 2d is discontinuous in x with peaks at md−(d+1)/2 where 0<m≤floor ((2ⁿ⁺¹+d−1)/2d) and troughs at md−(d−1)/2 for 0<m≤floor ((2ⁿ⁺¹+d−3)/2d). It suffices to check the upper bound error condition is met for the peaks and the lower bound condition is met for the troughs:

$$\begin{matrix}2 ( md - \frac{d - 1}{2} ) ( 1 - \frac{ad}{{2}^{k}} ) - \frac{bd}{{2}^{k - 1}} + d \leq 1 \\ 2 m ( {2}^{k} - ad ) \leq 2 b - a ( d - 1 ) \\ where 0 < m \leq ⌊ \frac{{2}^{n + 1} + d - 3}{2 d} ⌋\end{matrix}$$

$$\begin{matrix}2 d - 1 < 2 ( md - \frac{d + 1}{2} ) ( 1 - \frac{ad}{{2}^{k}} ) - \frac{bd}{{2}^{k - 1}} + 3 d \\ 2 m ( ad - {2}^{k} ) < a ( d + 1 ) - 2 b \\ where 0 < m \leq ⌊ \frac{{2}^{n + 1} + d - 1}{2 d} ⌋\end{matrix}$$

Now given that a and d is odd then ad−2^{k≠0}. Depending on the sign of ad−2^{k} different values of m will stress these inequalities. It follows that the necessary and sufficient conditions for implementation of round towards nearest for the IC design is:

$$\begin{matrix}⌊ \frac{x}{d} + \frac{1}{2} ⌋ = ⌊ \frac{ax + b}{{2}^{k}} ⌋ \\ x ∈ [ 0 , {2}^{n} - 1 ]\end{matrix} ⇔ \begin{matrix}\frac{a ( d - 1 ) - 2 b - 1}{2 ⌊ {2}^{n + 1} + d - 3 ) / 2 d ⌋} < ad - {2}^{k} < a ( \frac{d + 1}{2} ) - b if ad - {2}^{k} < 0 \\ a ( \frac{d - 1}{2} ) - b \leq ad - {2}^{k} < \frac{a ( d + 1 ) - 2 b}{2 ⌊ ( {2}^{n + 1} + d - 1 ) / 2 d ⌋} if ad - {2}^{k} > 0\end{matrix}$$

### Faithful Rounding (FR1)

In this case we can return either integer that lies either side of the true side, if the true answer is an integer we must return that integer:

$$\begin{matrix}Case x = md \\ 0 \leq m \leq ⌊ {2}^{n} / d ⌋\end{matrix} \begin{matrix}m = ⌊ \frac{amb + b}{{2}^{k}} ⌋ \\ 0 \leq \frac{amb + b}{{2}^{k}} - m < 1 \\ - b \leq m ( ad - {2}^{k} ) < {2}^{k} - b\end{matrix}$$

$$Case x mod d > 0$$

$$\begin{matrix}0 \leq \frac{ax + b}{{2}^{k}} - ⌊ \frac{x}{d} ⌋ < 2 \\ x ( 1 - \frac{ad}{{2}^{k}} ) - \frac{bd}{{2}^{k}} \leq x mod d < x ( 1 - \frac{ad}{{2}^{k}} ) - \frac{bd}{{2}^{k}} + 2 d\end{matrix}$$

5

Now for the second case the sawtooth function x mod d is discontinuous in x with peaks at x=md−1 where 0<m≤floor(2ⁿ/d) and troughs at x=md+1 (note we are assuming x≠md) for 0≤m≤floo (2ⁿ/d). It suffices to check that the upper bound error condition is met for md−1 and the lower bound error condition is met for md+1:

$$\begin{matrix}( md + 1 ) ( 1 - \frac{ad}{{2}^{k}} ) - \frac{bd}{{2}^{k}} \leq 1 \\ m ( {2}^{k} - ad ) \leq a + b \\ where 0 < m \leq ⌊ \frac{{2}^{n}}{d} ⌋\end{matrix} \begin{matrix}d - 1 < ( md - 1 ) ( 1 - \frac{ad}{{2}^{k}} ) - \frac{bd}{{2}^{k}} + 2 d \\ m ( ad - {2}^{k} ) < {2}^{k} + a - b \\ where 0 < m \leq ⌊ \frac{{2}^{n}}{d} ⌋\end{matrix}$$

k Now given that a and d is odd then ad−2^{k≠0}. Depending on the sign of ad−2^{k} different values of m will stress these inequalities in the two cases. It follows that the necessary and sufficient conditions for implementation of faithful rounding is:

$$\begin{matrix}⌊ \frac{x}{d} ⌋ or ⌈ \frac{x}{d} ⌉ = ⌊ \frac{ax + b}{{2}^{k}} ⌋ \\ x ∈ [ 0 , {2}^{n} - 1 ]\end{matrix} ⇔ \begin{matrix}⌊ {2}^{n} / d ⌋ ( {2}^{k} - ad ) \leq b < {2}^{k} if ad - {2}^{k} < 0 \\ ⌊ {2}^{n} / d ⌋ ( ad - {2}^{k} ) < {2}^{k} - b if ad - {2}^{k} > 0\end{matrix}$$

### Minimal Hardware Implementation Scheme

Minimal hardware implementations in the IC will result from minimising the number of partial product bits in ax+b. The scheme used achieves this as follows:
1 Minimise k producing kopt.
2 For the range of acceptable values of a for a given kopt choose the one that results in the smallest constant multiplier. This can be accomplished by choosing a value for a which has the smallest number of non zero elements in a Canonical Signed Digit representation of a. This will result in aopt. Define this function as minCSD(x).
3 For the range of valid values for b having fixed kopt and aopt choose the one with smallest Hamming weight, as this minimises the number of partial products bits. If there are a range of numbers that have smallest Hamming weight, we choose the one that has smallest value as this will add Is into the least significant bits of the array where the height of the array is smallest. Define the function which finds this value for numbers in the interval [a, b] as minHamm(a, b). Note that the minHamm(a, b) function can be computed as follows:

```
Input unsigned a[p − 1 : 0],b[p − 1 : 0]
Output unsigned c[p − 1 : 0]
c = 0
for i = p − 1; i ≥ 0; i − −
loop
  if a[i] == b[i] then c[i] = a[i]; a[i] = 0;
  else c+ = 2^{┌log}₂ ^{a┐}; break;
endloop
return c
```

Now applying this scheme to the space of allowable (a,b,k) as derived by the rounding mode and set of conditions we can construct a minimal hardware implementation for each of the three rounding schemes:

### Rtz Minimal Hardware Implementation When ad−2^{K}>0

In this case we require:

$$a d - {2}^{k} < \frac{a - b}{⌊ {2}^{n} / d ⌋}$$

Now note that the right hand side is strictly decreasing in b. So for any valid a, b and k we can always set b=0 and then the condition will still be met, plus it will cost less hardware to implement. Hence a minimal hardware implementation will have b=0. Thus our condition reduces to:

$$( ad - {2}^{k} ) ⌊ {2}^{n} / d ⌋ < a$$

$$\frac{{2}^{k}}{d} < a < \frac{{2}^{k} ⌊ {2}^{n} / d ⌋}{d ⌊ {2}^{n} / d ⌋ - 1}$$

Given that a must be an integer we have a formula for kopt:

$${k}_{opt} = min ( k : \frac{1}{{2}^{k}} ⌈ \frac{{2}^{k}}{d} ⌉ < \frac{⌊ {2}^{n} / d ⌋}{d ⌊ {2}^{n} / d ⌋ - 1} )$$

$${k}_{opt} = min ( k : \frac{{2}^{k}}{( - {2}^{k} ) mod d} < d ⌊ \frac{{2}^{n}}{d} ⌋ - 1 )$$

And kopt is the smallest such valid k hence:

$$\frac{1}{{2}^{{k}_{opt} - 1}} ⌈ \frac{{2}^{{k}_{opt} - 1}}{d} ⌉ \geq \frac{⌊ {2}^{n} / d ⌋}{d ⌊ {2}^{n} / d ⌋ - 1}$$

$$2 ⌈ \frac{{2}^{{k}_{opt} - 1}}{d} ⌉ \geq \frac{{2}^{{k}_{opt}} ⌊ {2}^{n} / d ⌋}{d ⌊ {2}^{n} / d ⌋ - 1}$$

$$⌈ \frac{{2}^{{k}_{opt}}}{d} ⌉ + 1 \geq \frac{{2}^{{k}_{opt}} ⌊ {2}^{n} / d ⌋}{d ⌊ {2}^{n} / d ⌋ - 1}$$

Hence a=ceil(2^{k}^{ₒₚₜ}/d) is valid but a=ceil(2^{k}^{ₒₚₜ}/d)+1 is not valid. It follows that the there is only valid value for a when k=kopt. We can now state that the design which minimises k and satisfies ad−2⁶>0 is unique and is defined by:

$${k}_{opt}^{+} = min ( k : \frac{{2}^{k}}{( - {2}^{k} ) mod d} > d ⌊ \frac{{2}^{n}}{d} ⌋ - 1 )$$

$${a}_{opt}^{+} = ⌈ \frac{{2}^{{k}_{opt}^{+}}}{d} ⌉$$

$${b}_{opt}^{+} = 0$$

### K RTZ Minimal Hardware Implementation When ad−2^{K}>0

In this case we need:

$$- \frac{b + 1}{⌊ {2}^{n} / d ⌋} < ad - {2}^{k} < a - b$$

Hence b must necessarily be in the following interval:

$$b ∈ [ ( {2}^{k} - ad ) ⌊ {2}^{n} / d ⌋ , {2}^{k} + a - ad - 1 ]$$

This interval must be non empty so:

$${2}^{k} + a - ad > ( {2}^{k} - ad ) ⌊ {2}^{n} / d ⌋$$

$$\frac{{2}^{k}}{d} > a > \frac{{2}^{k} ( ⌊ {2}^{n} / d ⌋ - 1 )}{d ⌊ {2}^{n} / d ⌋ - d + 1}$$

Given that a must be an integer we have a formula for kopt:

$${k}_{opt} = min ( k : \frac{1}{{2}^{k}} ⌊ \frac{{2}^{k}}{d} ⌋ > \frac{⌊ {2}^{n} / d ⌋ - 1}{d ⌊ {2}^{n} / d ⌋ - d + 1} )$$

$${k}_{opt} = min ( k : \frac{{2}^{k}}{{2}^{k} mod d} > d ⌊ \frac{{2}^{n}}{d} ⌋ - d + 1 )$$

Where kopt is the smallest such valid k hence:

$$\frac{1}{{2}^{{k}_{opt} - 1}} ⌈ \frac{{2}^{{k}_{opt} - 1}}{d} ⌉ \leq \frac{⌊ {2}^{n} / d ⌋ - 1}{d ⌊ {2}^{n} / d ⌋ - d + 1}$$

$$2 ⌈ \frac{{2}^{{k}_{opt} - 1}}{d} ⌉ \leq \frac{{2}^{{k}_{opt}} ( ⌊ {2}^{n} / d ⌋ - 1 )}{d ⌊ {2}^{n} / d ⌋ - d + 1}$$

$$⌈ \frac{{2}^{{k}_{opt}}}{d} ⌉ - 1 \leq \frac{{2}^{{k}_{opt}} ( ⌊ {2}^{n} / d ⌋ - 1 )}{d ⌊ {2}^{n} / d ⌋ - d + 1}$$

Hence a=floor(2^{k}^{ₒₚₜ}/d) is valid but a=floor((2^{k}^{ₒₚₜ}/d)−1 is not valid. It follows that the there is only valid value for a when k=kopt. We can now state that the design which minimises k k and satisfies ad−2^{k}>0 is unique in k and a and is defined by:

$${k}_{opt}^{-} = min ( k : \frac{{2}^{k}}{{2}^{k} mod d} > d ⌊ \frac{{2}^{n}}{d} ⌋ - d + 1 )$$

$${a}_{opt}^{-} = ⌊ \frac{{2}^{{k}_{opt}^{-}}}{d} ⌋$$

$${b}_{opt}^{-} = min Hamm ( ( {2}^{{k}_{opt}^{-}} - {a}_{opt}^{-} d ) ⌊ {2}^{n} / d ⌋ , {2}^{{k}_{opt}^{-}} - {a}_{opt}^{-} ( d - 1 ) - 1 )$$

Where minHamm(a, b) returns the number of smallest value from the numbers of smallest Hamming weight found within the interval[a, b].

### RTZ Minimal Hardware Design

Summarising the previous sections we have the following algorithm:

$${k}_{opt}^{+} = min ( k : \frac{{2}^{k}}{( - {2}^{k} ) mod d} > d ⌊ \frac{{2}^{n}}{d} ⌋ - 1 )$$

$${a}_{opt}^{+} = ⌈ \frac{{2}^{{k}_{opt}^{+}}}{d} ⌉$$

$${b}_{opt}^{+} = 0$$

$${k}_{opt}^{-} = min ( k : \frac{{2}^{k}}{{2}^{k} mod d} > d ⌊ \frac{{2}^{n}}{d} ⌋ - d + 1 )$$

$${a}_{opt}^{-} = ⌊ \frac{{2}^{{k}_{opt}^{-}}}{d} ⌋$$

$${b}_{opt}^{-} = min Hamm ( ( {2}^{{k}_{opt}^{-}} - {a}_{opt}^{-} d ) ⌊ {2}^{n} / d ⌋ , {2}^{{k}_{opt}^{-}} - {a}_{opt}^{-} ( d - 1 ) - 1 )$$

$$\{ {k}_{opt} , {a}_{opt} , {b}_{opt} \} = ( {k}_{opt}^{+} < {k}_{opt}^{-} ) ? \{ {k}_{opt}^{+} , {a}_{opt}^{+} , {b}_{opt}^{+} \} : \{ {k}_{opt}^{-} , {a}_{opt}^{-} , {b}_{opt}^{-} \}$$

Note that kopt⁺ is never equal to kopt⁻, otherwise if kopt=kopt⁺=kopt⁻ then:

$$\frac{{2}^{k}}{( - {2}^{k} ) mod d} > d ⌊ \frac{{2}^{n}}{d} ⌋ - 1 \geq \frac{{2}^{k - 1}}{( - {2}^{k - 1} ) mod d}$$

$$\frac{{2}^{k}}{{2}^{k} mod d} > d ⌊ \frac{{2}^{n}}{d} ⌋ - d + 1 \geq \frac{{2}^{k - 1}}{{2}^{k - 1} mod d}$$

Simplifying these two conditions we get:

$$2 ( ( - {2}^{k - 1} ) mod d ) > ( - {2}^{k} ) mod d$$

$$2 ( {2}^{k - 1} mod d ) > {2}^{k} mod d$$

$$2 ( {2}^{k - 1} mod d ) > {2}^{k} mod d > 2 ( {2}^{k - 1} mod d ) - d$$

This is a contradiction as 2^{k} mod d is equal to one of these limits.

### RTN Minimal Hardware Implementation When ad−2^{K}>0

In this case we need:

$$a ( \frac{d - 1}{2} ) - b \leq ad - {2}^{k} < \frac{a ( d + 1 ) - 2 b}{2 ⌊ ( {2}^{n + 1} + d - 1 ) / 2 d ⌋}$$

Hence b must necessarily be in the following interval:

$$b ∈ [ a ( \frac{d - 1}{2} ) + {2}^{k} - ad , a ( \frac{d + 1}{2} ) + ( {2}^{k} - ad ) ⌊ \frac{{2}^{n + 1} + d - 1}{2 d} ⌋ - 1 ]$$

This interval must be non empty so:

$$a ( \frac{d + 1}{2} ) + ( {2}^{k} - ad ) ⌊ \frac{{2}^{n + 1} + d - 1}{2 d} ⌋ > a ( \frac{d - 1}{2} ) + {2}^{k} - ad \\ \frac{{2}^{k}}{d} < a < \frac{{2}^{k} ⌊ ( {2}^{n + 1} - d - 1 ) / 2 d ⌋}{d ⌊ ( {2}^{n + 1} - d - 1 ) / 2 d ⌋ - 1}$$

Given that a must be an integer we have a formula for kopt:

$${k}_{opt} = min ( k : \frac{1}{{2}^{k}} ⌈ \frac{{2}^{k}}{d} ⌉ < \frac{⌊ ( {2}^{n + 1} - d - 1 ) / 2 d ⌋}{d ⌊ ( {2}^{n + 1} - d - 1 ) / 2 d ⌋ - 1} ) \\ {k}_{opt} = min ( k : \frac{{2}^{k}}{( - {2}^{k} ) mod d} > d ⌊ \frac{{2}^{n + 1} - d - 1}{2 d} ⌋ - 1 )$$

Where kopt is the smallest such valid k hence:

$$\frac{1}{{2}^{{k}_{opt} - 1}} ⌈ \frac{{2}^{{k}_{opt} - 1}}{d} ⌉ \geq \frac{⌊ ( {2}^{n + 1} - d - 1 ) / 2 d ⌋}{d ⌊ ( {2}^{n + 1} - d - 1 ) / 2 d ⌋ - 1} \\ 2 ⌈ \frac{{2}^{{k}_{opt} - 1}}{d} ⌉ \geq \frac{{2}^{{k}_{opt}} ⌊ ( {2}^{n + 1} - d - 1 ) / 2 d ⌋}{d ⌊ ( {2}^{n + 1} - d - 1 ) / 2 d ⌋ - 1} \\ ⌈ \frac{{2}^{{k}_{opt}}}{d} ⌉ + 1 \geq \frac{{2}^{{k}_{opt}} ⌊ ( {2}^{n + 1} - d - 1 ) / 2 d ⌋}{d ⌊ ( {2}^{n + 1} - d - 1 ) / 2 d ⌋ - 1}$$

Hence a=ceil(2ⁿ/d) is valid but a-ceil (2ⁿ/d)+1 is not valid. It follows that the there is only valid value for a when k=kopt. The design which minimises k and satisfies ad−2^{k}>0 is unique and is defined by:

$${k}_{opt}^{+} = min ( k : \frac{{2}^{k}}{( - {2}^{k} ) mod d} > d ⌊ \frac{{2}^{n + 1} - d - 1}{2 d} ⌋ - 1 ) \\ {a}_{opt}^{+} = ⌈ \frac{{2}^{{k}_{opt}^{+}}}{d} ⌉ \\ {b}_{opt}^{+} = min Hamm ( {a}_{opt}^{+} ( \frac{d - 1}{2} ) + {2}^{{k}_{opt}^{+}} - {a}_{opt}^{+} d , \\ {a}_{opt}^{+} ( \frac{d + 1}{2} ) + ( {2}^{{k}_{opt}^{+}} - {a}_{opt}^{+} d ) ⌊ \frac{{2}^{n + 1} + d - 1}{2 d} ⌋ - 1 )$$

Where minHamm(a, b) returns the number of smallest value from the numbers of smallest Hamming weight found within the interval[a, b].

### RTN Minimal Hardware Implementation When ad−2^{K}>0

In this case we need:

$$\frac{a ( d - 1 ) - 2 b - 1}{2 ⌊ ( {2}^{n + 1} + d - 3 ) / 2 d ⌋} < ad - {2}^{k} < a ( \frac{d + 1}{2} ) - b$$

Hence b must necessarily be in the following interval:

$$b ∈ [ a ( \frac{d - 1}{2} ) + ( {2}^{k} - ad ) ⌊ \frac{{2}^{n + 1} + d - 3}{2 d} ⌋ , a ( \frac{d + 1}{2} ) + {2}^{k} - ad - 1 ]$$

This interval must be non empty so:

$$a ( \frac{d + 1}{2} ) + {2}^{k} - ad > a ( \frac{d - 1}{2} ) + ( {2}^{k} - ad ) ⌊ \frac{{2}^{n + 1} + d - 3}{2 d} ⌋ \\ \frac{{2}^{k}}{d} > a > \frac{{2}^{k} ⌊ ( {2}^{n + 1} - d - 3 ) / 2 d ⌋}{d ⌊ ( {2}^{n + 1} - d - 3 ) / 2 d ⌋ + 1}$$

Given that a must be an integer we have a formula for kopt:

$${k}_{opt} = min ( k : \frac{1}{2} ⌊ \frac{{2}^{k}}{d} ⌋ > \frac{⌊ ( {2}^{n + 1} - d - 3 ) / 2 d ⌋}{d ⌊ ( {2}^{n + 1} - d - 3 ) / 2 d ⌋ + 1} ) \\ {k}_{opt} = min ( k : \frac{{2}^{k}}{{2}^{k} mod d} > d ⌊ \frac{{2}^{n + 1} - d - 3}{2 d} ⌋ + 1 )$$

Where kopt is the smallest such valid k hence:

$$\frac{1}{{2}^{{k}_{opt} - 1}} ⌊ \frac{{2}^{{k}_{opt} - 1}}{d} ⌋ \leq \frac{⌊ ( {2}^{n + 1} - d - 3 ) / 2 d ⌋}{d ⌊ ( {2}^{n + 1} - d - 3 ) / 2 d ⌋ + 1} \\ 2 ⌊ \frac{{2}^{{k}_{opt} - 1}}{d} ⌋ \leq \frac{{2}^{{k}_{opt}} ⌊ ( {2}^{n + 1} - d - 3 ) / 2 d ⌋}{d ⌊ ( {2}^{n + 1} - d - 3 ) / 2 d ⌋ + 1} \\ ⌊ \frac{{2}^{{k}_{opt}}}{d} ⌋ - 1 \leq \frac{{2}^{{k}_{opt}} ⌊ ( {2}^{n + 1} - d - 3 ) / 2 d ⌋}{d ⌊ ( {2}^{n + 1} - d - 3 ) / 2 d ⌋ + 1}$$

Hence a=floor(2^{k}^{ₒₚₜ}/d) is valid but a=floor((2^{k}^{ₒₚₜ}/d)−1 is not valid. It follows that the there is only valid value for a when k=kopt. The design which minimises k and satisfies ad−2^{k}<0 is unique in k and a and is defined by:

$${k}_{opt}^{-} = min ( k : \frac{{2}^{k}}{{2}^{k} mod d} > d ⌊ \frac{{2}^{n + 1} - d - 3}{2 d} ⌋ + 1 ) \\ {a}_{opt}^{-} = ⌊ \frac{{2}^{{k}_{opt}^{-}}}{d} ⌋ \\ {b}_{opt}^{-} = min Hamm ( {a}_{opt}^{-} ( \frac{d - 1}{2} ) + ( {2}^{{k}_{opt}^{-}} - {a}_{opt}^{-} d ) ⌊ \frac{{2}^{n + 1} + d - 3}{2 d} ⌋ , \\ {a}_{opt}^{-} ( \frac{d + 1}{2} ) + {2}^{{k}_{opt}^{-}} - {a}_{opt}^{-} d - 1 )$$

Where minHamm a, b) returns the number of smallest value from the numbers of smallest Hamming weight found within the interval[a, b].

### RTN Minimal Hardware Design

Summarising the previous sections results in the following algorithm:

$${k}_{opt}^{+} = min ( k : \frac{{2}^{k}}{( - {2}^{k} ) mod d} > d ⌊ \frac{{2}^{n + 1} - d - 1}{2 d} ⌋ - 1 )$$

$${a}_{opt}^{+} = ⌈ \frac{{2}^{{k}_{opt}^{+}}}{d} ⌉$$

$${b}_{opt}^{+} = min Hamm ( {a}_{opt}^{+} ( \frac{d - 1}{2} ) + {2}^{{k}_{opt}^{+}} - {a}_{opt}^{+} d ,$$

$${a}_{opt}^{+} ( \frac{d + 1}{2} ) + ( {2}^{{k}_{opt}^{+}} - {a}_{opt}^{+} d ) ⌊ \frac{{2}^{n + 1} + d - 1}{2 d} ⌋ - 1 )$$

$${k}_{opt}^{-} = min ( k : \frac{{2}^{k}}{{2}^{k} mod d} > d ⌊ \frac{{2}^{n + 1} - d - 3}{2 d} ⌋ + 1 )$$

$${a}_{opt}^{-} = ⌊ \frac{{2}^{{k}_{opt}^{-}}}{d} ⌋$$

$${b}_{opt}^{-} = min Hamm ( {a}_{opt}^{-} ( \frac{d - 1}{2} ) + ( {2}^{{k}_{opt}^{-}} - {a}_{opt}^{-} d ) ⌊ \frac{{2}^{n + 1} + d - 3}{2 d} ⌋ ,$$

$${a}_{opt}^{-} ( \frac{d + 1}{2} ) + {2}^{{k}_{opt}^{-}} - {a}_{opt}^{-} d - 1 )$$

$$\{ {k}_{opt} , {a}_{opt} , {b}_{opt} \} = ( {k}_{opt}^{+} < {k}_{opt}^{-} ) ? \{ {k}_{opt}^{+} , {a}_{opt}^{+} , {b}_{opt}^{+} \} : \{ {k}_{opt}^{-} , {a}_{opt}^{-} , {b}_{opt}^{-} \}$$

Note that kopt⁺ is never equal to kopt⁻, otherwise if kopt=kopt⁺=kopt⁻ then:

$$\frac{{2}^{k}}{( - {2}^{k} ) mod d} > d ⌊ \frac{{2}^{n + 1} - d - 1}{2 d} ⌋ - 1 \geq \frac{{2}^{k - 1}}{( - {2}^{k - 1} ) mod d} \\ \frac{{2}^{k}}{{2}^{k} mod d} > d ⌊ \frac{{2}^{n + 1} - d - 3}{2 d} ⌋ + 1 \geq \frac{{2}^{k - 1}}{{2}^{k - 1} mod d}$$

Simplifying these two conditions we get:

$$2 ( ( - {2}^{k - 1} ) mod d ) > ( - {2}^{k} ) mod d \\ 2 ( {2}^{k - 1} mod d ) > {2}^{k} mod d \\ 2 ( {2}^{k - 1} mod d ) > {2}^{k} mod d > 2 ( {2}^{k - 1} mod d ) - d$$

This is a contradiction as 2^{k} mod d is equal to one of these limits.

### FR1 Minimal Hardware Implementation When ad−2^{K}>0

In this case we require:

$$⌊ {2}^{n} / d ⌋ ( ad - {2}^{k} ) < {2}^{k} - b$$

Now note that the right hand side is strictly decreasing in b. So for any valid a, b and k we can always set b=0 and then condition will still be met, plus cost less hardware to implement. Hence minimal hardware implementations will have b=0. Thus our condition reduces to:

$$⌊ {2}^{n} / d ⌋ ( ad - {2}^{k} ) < {2}^{k} \\ \frac{{2}^{k}}{d} < a < \frac{{2}^{k} ⌈ {2}^{n} / d ⌉}{d ⌊ {2}^{n} / d ⌋}$$

Given that a must be an integer we have a formula for kopt:

$${k}_{opt} = min ( k : \frac{1}{{2}^{k}} ⌈ \frac{{2}^{k}}{d} ⌉ < \frac{⌈ {2}^{n} / d ⌉}{d ⌊ {2}^{n} / d ⌋} )$$

$${k}_{opt} = min ( k : \frac{{2}^{k}}{( - {2}^{k} ) mod d} > ⌊ \frac{{2}^{n}}{d} ⌋ )$$

Where kopt is the smallest such valid k hence:

$$\frac{1}{{2}^{{k}_{opt} - 1}} ⌈ \frac{{2}^{{k}_{opt} - 1}}{d} ⌉ \geq \frac{⌈ {2}^{n} / d ⌉}{d ⌊ {2}^{n} / d ⌋}$$

$$2 ⌈ \frac{{2}^{{k}_{opt} - 1}}{d} ⌉ \geq \frac{{2}^{{k}_{opt}} ⌈ {2}^{n} / d ⌉}{d ⌊ {2}^{n} / d ⌋}$$

$$⌈ \frac{{2}^{{k}_{opt}}}{d} ⌉ + 1 \geq \frac{{2}^{{k}_{opt}} ⌈ {2}^{n} / d ⌉}{d ⌊ {2}^{n} / d ⌋}$$

Hence a=ceil(2^{k}^{ₒₚₜ}/d) is valid but a=ceil(2^{k}^{ₒₚₜ}/d)+1 is not valid. It follows that the there is only a valid value for a when k=kopt. We can now state that the design which minimises k and satisfies ad−2^{k}>0 is unique and is defined by:

$${k}_{opt}^{+} = min ( k : \frac{{2}^{k}}{( - {2}^{k} ) mod d} > ⌊ \frac{{2}^{n}}{d} ⌋ )$$

$${a}_{opt}^{+} = ⌈ \frac{{2}^{{k}_{opt}^{+}}}{d} ⌉$$

$${b}_{opt}^{+} = 0$$

### FR1 Minimal Hardware Implementation When ad−2^{K}>0

In this case we need:

$$⌊ {2}^{n} / d ⌋ ( {2}^{k} - a d ) \leq b < {2}^{k}$$

Now b must live in a non empty interval so:

$${2}^{k} > ⌊ {2}^{n} / d \vert ( {2}^{k} - ad )$$

$$\frac{{2}^{k}}{d} > a > \frac{{2}^{k} ( ⌊ {2}^{n} / d ⌋ - 1 )}{d ⌊ {2}^{n} / d ⌋}$$

Given that a must be an integer we have a formula for kopt:

$${k}_{opt} = min ( k : \frac{1}{{2}^{k}} ⌊ \frac{{2}^{k}}{d} ⌋ < \frac{⌊ {2}^{n} / d ⌋ - 1}{d ⌊ {2}^{n} / d ⌋} )$$

$${k}_{opt} = min ( k : \frac{{2}^{k}}{{2}^{k} mod d} > ⌊ \frac{{2}^{n}}{d} ⌋ )$$

Where kopt is the smallest such valid k hence:

$$\frac{1}{{2}^{{k}_{opt} - 1}} ⌊ \frac{{2}^{{k}_{opt} - 1}}{d} ⌋ \leq \frac{⌊ {2}^{n} / d ⌋ - 1}{d ⌊ {2}^{n} / d ⌋}$$

$$2 ⌊ \frac{{2}^{{k}_{opt} - 1}}{d} ⌋ \leq \frac{{2}^{{k}_{opt}} ( ⌊ {2}^{n} / d ⌋ - 1 )}{d ⌊ {2}^{n} / d ⌋}$$

$$⌊ \frac{{2}^{{k}_{opt}}}{d} ⌋ - 1 \leq \frac{{2}^{{k}_{opt}} ( ⌊ {2}^{n} / d ⌋ - 1 )}{d ⌊ {2}^{n} / d ⌋}$$

kopt Hence a=floor(2^{k}^{ₒₚₜ}/d) is valid but a=floor(2^{k}^{ₒₚₜ}/d)−1 is not valid. It follows that the there is only a valid value for a when k=kopt. We can now state that the design which minimises k and satisfies ad−2^{k}<0 is unique in k and a and is defined by:

$${k}_{opt}^{-} = min ( k : \frac{{2}^{k}}{{2}^{k} mod d} > ⌊ \frac{{2}^{n}}{d} ⌋ )$$

$${a}_{opt}^{-} = ⌊ \frac{{2}^{{k}_{opt}^{-}}}{d} ⌋$$

$${b}_{opt}^{-} = minHamm ( ( {2}^{{k}_{opt}^{-}} - {a}_{opt}^{-} d ) ⌊ {2}^{n} / d ⌋ , {2}^{{k}_{opt}^{-}} - 1 )$$

Where minHamm(a, b) returns the number of smallest value from the numbers of smallest Hamming weight found within the interval[a, b].

### FR1 Minimal Hardware Design

Summarising the previous sections we have the following algorithm:

$${k}_{opt}^{+} = min ( k : \frac{{2}^{k}}{( - {2}^{k} ) mod d} > ⌊ \frac{{2}^{n}}{d} ⌋ )$$

$${a}_{opt}^{+} = ⌈ \frac{{2}^{{k}_{opt}^{+}}}{d} ⌉$$

$${b}_{opt}^{+} = 0$$

$${k}_{opt}^{-} = min ( k : \frac{{2}^{k}}{{2}^{k} mod d} > ⌊ \frac{{2}^{n}}{d} ⌋ )$$

$${a}_{opt}^{-} = ⌊ \frac{{2}^{{k}_{opt}^{-}}}{d} ⌋$$

$${b}_{opt}^{-} = minHamm ( ( {2}^{{k}_{opt}^{-}} - {a}_{opt}^{-} d ) ⌊ {2}^{n} / d ⌋ , {2}^{{k}_{opt}^{-}} - 1 )$$

$$\{ {k}_{opt} , {a}_{opt} , {b}_{opt} \} = ( {k}_{opt}^{+} < {k}_{opt}^{-} ) ? \{ {k}_{opt}^{+} , {a}_{opt}^{+} , {b}_{opt}^{+} \} : \{ {k}_{opt}^{-} , {a}_{opt}^{-} , {b}_{opt}^{-} \}$$

Note that kopt⁺ is never equal to kopt⁻, else if kopt=kopt⁺=kopt⁻ then:

$$\frac{{2}^{k}}{( - {2}^{k} ) mod d} > ⌊ \frac{{2}^{n}}{d} ⌋ \geq \frac{{2}^{k - 1}}{( - {2}^{k - 1} ) mod d}$$

$$\frac{{2}^{k}}{{2}^{k} mod d} > ⌊ \frac{{2}^{n}}{d} ⌋ \geq \frac{{2}^{k - 1}}{{2}^{k - 1} mod d}$$

Simplifying these two conditions we get:

$$2 ( ( - {2}^{k - 1} ) mod d ) > ( - {2}^{k} ) mod d$$

$$2 ( {2}^{k - 1} mod d ) > {2}^{k} mod d$$

$$2 ( {2}^{k - 1} mod d ) > {2}^{k} mod d > 2 ( {2}^{k - 1} mod d ) - d$$

This is a contradiction as 2^{k} mod d is equal to one of these limits.

### Invariant Integer Division Synthesiser

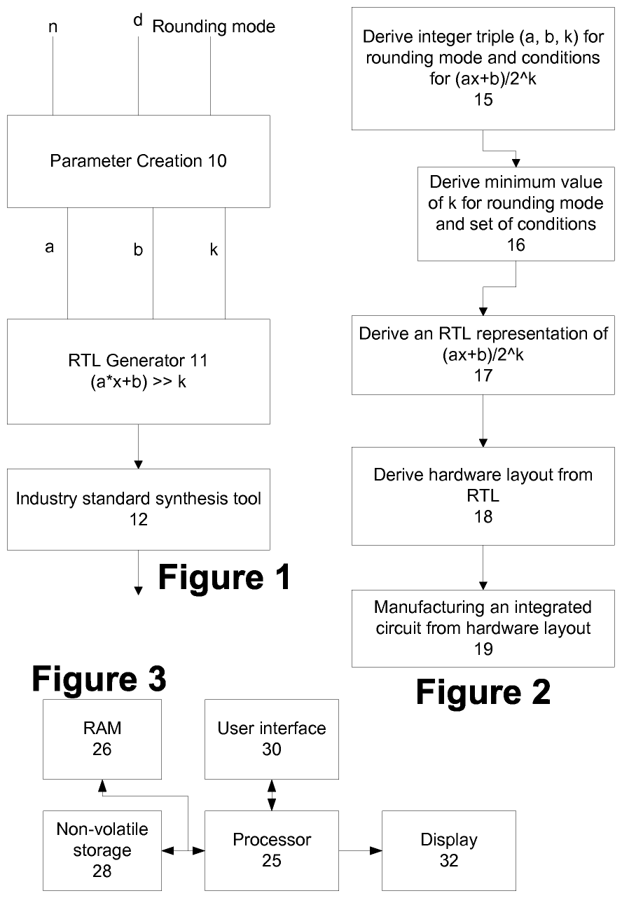

Example structure of a synthesis apparatus according to the disclosure that performs invariant integer division is depicted in FIG. 1.

This shows a parameter creation unit 2 which has three inputs n, d and rounding mode. n is the number of bits to be used in the numerator of the division, d is the divisor, and the rounding mode is a selection of one of a plurality of rounding modes. Three examples are given here but others are possible.

The parameter creation unit 2 generates in dependence on the inputs n, d, and rounding mode, the integer triple (a, b, k) required by an RTL generator k to generate an appropriate RTL representation of the circuitry for performing the division for the said number of bits of n and rounding mode, and for additional conditions provided to the RTL generation. The RTL generator is computer controlled to generate an RTL representation of a division for the integer triple using additional conditions such as ad−2^{k}<0.

The RTL representation is then output to a synthesis tool 6 which generates the hardware circuits required to implement the division on an appropriate part of an integrated circuit.

The algorithm in the parameter creation may be summarised as:

$$\{ k , a , b \} = ( {k}^{+} < k ) ? \{ {k}^{+} , {a}^{+} , minHamm ( {Y}^{+} ( {k}^{+} , {a}^{+} ) ) \} : \{ k , a , minHamm ( {Y}^{-} ( {k}^{-} , {a}^{-} ) ) \}$$

$$Where$$

$${k}^{+} = min ( k : \frac{{2}^{k}}{( - {2}^{k} ) mod d} > {X}^{+} ) {k}^{-} = min ( k : \frac{{2}^{k}}{{2}^{k} mod d} > {X}^{-} )$$

$${a}^{+} = ⌈ \frac{{2}^{{k}^{+}}}{d} ⌉ {a}^{-} = ⌊ \frac{{2}^{{k}^{-}}}{d} ⌋$$

And

| | RTZ | RTN | FR1 |
|---|---|---|---|
| X⁺ | $d ⌊ \frac{{2}^{n}}{d} ⌋ - 1$ | $d ⌊ \frac{{2}^{n + 1} - d - 1}{2 d} ⌋ - 1$ | $⌊ \frac{{2}^{n}}{d} ⌋$ |
| X⁻ | $d ⌊ \frac{{2}^{n}}{d} ⌋ - d + 1$ | $d ⌊ \frac{{2}^{n + 1} - d - 3}{2 d} ⌋ + 1$ | $⌊ \frac{{2}^{n}}{d} ⌋$ |
| Y⁺(k, a) | (0, 0) | $( \begin{matrix}a ( \frac{d - 1}{2} ) + {2}^{k} - ad , \\ a ( \frac{d - 1}{2} ) + ( {2}^{k} - ad ) ⌊ \frac{{2}^{n + 1} + d - 1}{2 d} ⌋ - 1\end{matrix} )$ | (0, 0) |
| Y⁻(k, a) | $( \begin{matrix}( {2}^{k} - ad ) ⌊ {2}^{n} / d ⌋ , \\ {2}^{k} - a ( d - 1 ) - 1\end{matrix} )$ | $( \begin{matrix}a ( \frac{d - 1}{2} ) + ( {2}^{k} - ad ) ⌊ \frac{{2}^{n + 1} + d - 3}{2 d} ⌋ , \\ a ( \frac{d - 1}{2} ) + {2}^{k} - ad - 1 ,\end{matrix} )$ | $( \begin{matrix}( {2}^{k} - ad ) ⌊ {2}^{n} / d ⌋ , \\ {2}^{k} - 1\end{matrix} )$ |

### Specific Example of the Idea: Application to the Multiplication of Normalised Numbers

An unsigned n bit normalised number x is interpreted as holding the value x/(2ⁿ−1). Multiplication of these numbers thus involves computing the following:

$$\frac{y}{{2}^{n} - 1} \approx \frac{a}{{2}^{n} - 1} \frac{b}{{2}^{n} - 1}$$

$$y \approx \frac{ab}{{2}^{n} - 1}$$

We can apply the previously found results to implementing this design for the three rounding modes. In this case d=2ⁿ−1 and given that ab≤(2ⁿ−1) then 2ⁿ−1 in the previous sections will be replaced by (2ⁿ−1)². Substituting these values into the previous sections gives rise to the following three rounding:

$$RTZ ( \frac{ab}{{2}^{n} - 1} ) = ⌊ \frac{( {2}^{n} + 1 ) ab + {2}^{n}}{{2}^{2 n}} ⌋$$

$$RTN ( \frac{a b}{{2}^{n} - 1} ) = ⌊ \frac{( {2}^{n} + 1 ) ( ab + {2}^{n - 1} )}{{2}^{2 n}} ⌋$$

$$FR 1 ( \frac{a b}{{2}^{n} - 1} ) = ⌊ \frac{a b + {2}^{n} - 1}{{2}^{n}} ⌋$$

Note that the RTN case gives a generalisation and proof of the formula for such multiplication [2]. Note that the allowable interval for the additive constant in each case is [2ⁿ−1, 2ⁿ+1], [2ⁿ⁻¹(2ⁿ+1)−2, 2ⁿ⁻¹(2ⁿ+1)] and no freedom for the FRI case.

### Alternative Implementations

Further implementations can be realized by those skilled in the art based on the following disclosures, to deal with the following situations:
1) d is even. Note that if d is a power of 2 then we have the trivial implementations:

$$R T Z ( \frac{x}{d} ) = F R 1 ( \frac{x}{d} ) = x ≫ {log}_{2} ( d )$$

$$RTN ( \frac{x}{d} ) = ( x + d / 2 ) ≫ {log}_{2} ( d )$$

2) If x lives in the interval [0,max] and not [0,2ⁿ−1] then it suffices to replace 2ⁿ the formulae above with max+1.
3) If x can take negative the formulae can be reworked using the framework established above.
4) Other rounding modes-the formulae can be reworked using the framework established above.
5) The hardware scheme has been chosen to minimize the size of the final shift-a different scheme could be applied which would result in different equations for optimal a, b and k.

In summary of the above, FIG. 1 depicts an example where a parameter creator inputs n, d, and a desired rounding mode, and outputs integer triple a, b, and k. An RTL generator 11 receives the a, b, and k. RTL generator 11 generates RTL for (a*x+b)>>k according to the parameters. The generated RTL is input to a synthesis tool 12, which outputs a hardware layout that can be fabricated in a fabrication process. FIG. 2 depicts an example method, where integer triple (a, b, k) is derived 15 for a rounding mode and conditions. At 16, a minimum value of k is derived (16 is depicted separately from 15, for ease of explanation). At 17, an RTL representation of (ax+b)/2\hat{ }k is derived. At 18, a hardware layout is derived from the RTL. At 19, a circuit can be manufactured according to the hardware layout. FIG. 3 depicts exemplary apparatus in which methods can be implemented. A processor 25 interfaces with a user interface 30 and with a display 32. A RAM 26 and non-volatile storage 28 interfaces with processor 25. These memories are tangible memories that can store instructions for configuring processor 25 to perform aspects of the disclosure.

What is claimed is:

1. A computer-implemented method for generating a representation of a circuit, the method comprising:
deriving, using a parameter creator, integer values of a, b and k which satisfy Round (x/d)=(ax+b)/2^{k} for a rounding mode, where x is a variable integer and dis an integer constant; and
generating, using a synthesis tool, a representation of a circuit for performing integer division x d for manufacture of the circuit, wherein the representation of the circuit is generated using a representation of the logical operation (ax+b)/2^{k} in accordance with the derived integer values of a, b and k.

2. The method of claim 1, wherein deriving the integer values a, b and k comprises deriving the integer values a, b and k to have a minimum value of k to satisfy Round (x/d)−(ax+b)/2^{k} for the rounding mode.

3. The method of claim 1, further comprising deriving, using a representation generator, the representation of the logical operation (ax+b)/2^{k} using the derived integer values of a, b and k.

4. The method of claim 1, wherein the representation of the logical operation (ax+b)/2^{k} is an RTL (Register Transfer Level) representation.

5. The method of claim 1, wherein the rounding mode is one of: (i) round towards zero, (ii) round to nearest, and (iii) faithful rounding.

6. The method of claim 1, wherein deriving the integer values of a, b and k comprises deriving a value for b from values of k and a in which the derived value of b has the smallest Hamming weight of the possible values of b satisfying Round (x/d)−(ax+b)/2^{k}.

7. The method of claim 1, further comprising manufacturing the circuit from the representation of the circuit.

8. The method of claim 1, wherein the derivation of k is different for different rounding modes.

9. A non-transitory computer readable medium having stored thereon computer executable instructions that when executed cause at least one processor to:
derive, using a parameter creator, integer values of a, b and k which satisfy Round (x/d)−(ax+b)/2^{k} for a rounding mode where x is a variable integer and dis an integer constant; and
generate, using a synthesis tool, a representation of a circuit for performing integer division x/d from a representation of the logical operation (ax+b)/2^{k} in accordance with the derived integer values of a, b and k for manufacture of the circuit.

10. The non-transitory computer readable medium of claim 9, wherein execution of the executable instructions cause the at least one processor to derive integer values of a, b and k to have a minimum value of k to satisfy Round (x/d)= (ax+b)/2^{k} for the rounding mode.

11. The non-transitory computer readable medium of claim 9, wherein execution of the executable instructions cause the at least one processor to derive, using a representation generator, the representation of the logical operation (ax+b)/2^{k} using the derived integer values of a, b and k.

12. The non-transitory computer readable medium of claim 9, wherein the representation of the logical operation (ax+b)/2^{k} is an RTL (Register Transfer Level) representation.

13. The non-transitory computer readable medium of claim 9, wherein the rounding mode is one of: (i) round towards zero, (ii) round to nearest, and (iii) faithful rounding.

14. The non-transitory computer readable medium of claim 9, wherein deriving the integer values of a, b and k comprises deriving a value for b from values of k and a in which the derived value of b has the smallest Hamming weight of the possible values of b satisfying Round (x/d)−(ax+b)/2^{k}.

15. The non-transitory computer readable medium of claim 9, wherein the derivation of k is different for different rounding modes.

16. A method of manufacturing, using a circuit manufacturing system, a circuit, the method comprising:
processing, using a layout processing system, a representation of the circuit so as to generate a circuit layout description of the circuit for performing integer division, the representation of the circuit being generated in accordance with a method comprising:
deriving, using a parameter creator, integer values of a, b and k which satisfy Round (x/d)=(ax+b)/2^{k} for a rounding mode, where x is a variable integer and d is an integer constant; and
generating, using a synthesis tool, the representation of the circuit for manufacture of the circuit, wherein the representation of the circuit is generated using a representation of the logical operation (ax+b)/2^{k} in accordance with the derived integer values of a, b and k; and
manufacturing, using a circuit generation system, the circuit for performing integer division according to the circuit layout description.
